(19) United States
(12) Patent Application Publication
(10) Pub. No.: US 2010/0253215 A1
(43) Pub. Date: Oct. 7, 2010

(54) ORGANIC ELECTROLUMINESCENCE DEVICE

(75) Inventors: Takefumi FUKAGAWA, Chino-shi (JP); Daisuke NISHIOKA, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/751,116

(22) Filed: Mar. 31, 2010

(30) Foreign Application Priority Data
Apr. 1, 2009 (JP) 2009-088693
Mar. 30, 2010 (JP) 2010-077490

(51) Int. Cl. H01L 51/54

(52) U.S. Cl. 313/504

(57) ABSTRACT

An organic electroluminescence device includes on a substrate a plurality of first electrodes, a partition structure having a plurality of openings corresponding to the positions of the first electrodes, an organic luminescent layer, a second electrode covering the partition structure and the organic luminescent layer, and a sealing layer or a sealing member covering the second electrode. The second electrode includes a first portion and a second portion that are separate from each other. The first portion covers the entire partition structure except the outer portion from the edge of the partition structure, and the organic luminescent layer. The second portion covers the outer portion from the edge of the partition structure and at least part of the external region around the partition structure.

### BACKGROUND

1. Technical Field

The present invention relates to an organic electroluminescence device (hereinafter referred to as organic EL device).

2. Related Art

A known organic EL device includes an organic EL element disposed on, for example, a glass substrate. The organic EL element includes a pair of electrodes and a multilayer composite disposed between the electrodes and including an organic luminescent layer (light-emitting layer made of an organic material). For sealing the organic EL device, a glass plate may be disposed over the multilayer composite with an epoxy adhesive applied therebetween. The adhesive is cured to act as a sealing layer.

In general, an inorganic sealing layer is formed to cover the entire surface of a pixel partition layer. The inorganic sealing layer can be formed by sputtering or chemical vapor deposition (CVD). From the viewpoint of enhancing the moisture resistance, it is preferable that the inorganic sealing layer be dense and have a thickness to some extent. Such a sealing layer, however, has such an internal stress as cracks the ends of the pixel partition layer, and consequently causes moisture penetration. The pixel partition layer is generally formed of resin such as photosensitive alkaline resin in view of easy manufacturing process. Accordingly, moisture penetrating through the cracks in the inorganic sealing layer diffuses in the pixel partition layer and reaches the light-emitting area.

To overcome this disadvantage, for example, JP-A-2007-141750 proposes a structure in which the inorganic sealing layer is covered with an organic buffer layer, and another inorganic sealing layer is further formed on the organic buffer layer.

However, this structure requires that the organic buffer layer spread outward more than the pixel partition layer, and that a frame portion be tapered at a sufficient angle and be large to some extent.

### SUMMARY

An advantage of some aspect of the invention is that it provides an organic EL device that can overcome the above disadvantage.

According to an aspect of the invention, an organic electroluminescence device is provided which includes on a substrate a plurality of first electrodes, a partition structure having a plurality of openings corresponding to the positions of the first electrodes, an organic luminescent layer, a second electrode covering the partition structure and the organic luminescent layer, and a sealing layer or a sealing member covering the second electrode. The second electrode includes a first portion and a second portion that are separate from each other. The first portion covers the entire partition structure except the outer portion from the edge of the partition structure, and the organic luminescent layer. The second portion covers the outer portion from the edge of the partition structure and at least part of the external region around the partition structure.

Since the second electrode is disposed outward from the edge of the partition structure, the second electrode can adsorb moisture penetrating through cracks in the sealing layer or sealing member to hinder the moisture from penetrating the partition structure. In this instance, the thickness of the second electrode is generally several tens of nanometers, and does not increase the frame width. Thus, the organic EL device can exhibit an enhanced moisture resistance while the frame width is reduced.

The second electrode may contain an alkaline-earth metal.

The second electrode of top emission organic EL elements is often made of an alkaline-earth metal, such as a magnesium-silver alloy. Alkaline-earth metals can exhibit sufficient electron injection ability, a low resistance and a high transmittance. In addition, it is known that alkaline-earth metals are easy to oxidize. Accordingly, alkaline-earth metal oxides, such as CaO, SrO and BaO, are often used as the getter in bottom emission organic EL elements. The second electrode made of an alkaline-earth metal is generally disposed between the partition structure and the sealing layer or sealing member.

Since such a second electrode is disposed outward from the edge of the partition structure, the alkaline-earth metal of the second electrode can adsorb moisture penetrating through cracks in the water sealing layer or sealing member to hinder the moisture from penetrating the partition structure. Thus, the second electrode can appropriately reduce or prevent the transfer of oxygen-containing substances, such as moisture and oxygen, from the exterior to the interior of the organic EL device. Consequently, the degradation of the organic luminescent layer in luminous efficiency and other properties can be favorably reduced or prevented.

The second electrode may have a thickness of 1 to 50 nm, preferably of 10 to 30 nm.

For a second electrode having electron injection ability, capable of being used as a getter, it is required that the second electrode have a thickness of at least 1 nm. However, an extremely large thickness of the second electrode may reduce the transmittance to visible light, and result in the degradation of image quality of the organic EL device. Thus, the second electrode formed as above can function as the getter and enhance the quality of displayed images.

The first portion and the second portion of the second electrode may be in the same layer.

Thus, the getter can be formed in the same layer as the second electrode on the substrate 40 by only preparing a mask for patterning. The manufacturing process can be simplified and the connection can be easy. For example, an ITO second electrode allows easy soldering and has a high adhesion to the sealing resin of the sealing layer.

The second portion of the second electrode may be disposed over the entirety of an outer region of the surface of the substrate.

Such the second portion is disposed over the entire outer region, the deoxidation/dehydration ability can be enhanced.

The second portion of the second electrode may be electrically floated.

In embodiments of the present invention, the second electrode is divided into two portions: a second portion spreading outward from the edge of the partition structure, and a first portion covering the organic luminescent layers and the entire partition structure except the outer portion from the edge of the partition structure. Thus, the second portion of the second electrode spreading outward from the edge of the partition structure can be electrically floated. Wiring is disposed at the end of the substrate. If the second electrode spread outward beyond the edge of the partition structure, a short circuit may occur between the second electrode and the wiring. By dividing the second electrode into the first portion and the second portion, a short circuit does not occur between the second electrode and the wiring even though an electric field is applied to the organic luminescent layer.

### BRIEF DESCRIPTION OF THE DRAWINGS

The invention will be described with reference to the accompanying drawings, wherein like numbers reference like elements.

FIG. 1 is an equivalent circuit diagram of an organic EL device according to a first embodiment of the invention.

FIG. 2 is a schematic sectional view of the organic EL device according to the first embodiment.

FIG. 3 is a fragmentary enlarged sectional view of portion III in FIG. 2.

FIGS. 4A to 4C are sectional views showing a manufacturing process of the organic EL device according to the first embodiment.

FIGS. 5A to 5C are sectional views showing the manufacturing process of the organic EL device according to the first embodiment.

FIGS. 6A to 6C are sectional views showing the manufacturing process of the organic EL device according to the first embodiment.

FIG. 7 is a plan view of a mask member used for the deposition performed in the step shown in FIG. 5C.

FIG. 8 is a schematic sectional view of an organic EL device according to a second embodiment of the invention.

FIG. 9 is a fragmentary enlarged sectional view of portion IX in FIG. 8.

FIG. 10 is a fragmentary enlarged sectional view of an organic EL device according to a third embodiment of the invention.

FIG. 11 is a fragmentary enlarged sectional view of an organic EL device according to a fourth embodiment of the invention.

FIG. 12 is a fragmentary enlarged sectional view of an organic EL device according to a fifth embodiment of the invention.

FIG. 13 is a fragmentary enlarged sectional view of an organic EL device according to a sixth embodiment of the invention.

FIG. 14 is a fragmentary enlarged sectional view of an organic EL device according to a seventh embodiment of the invention.

FIG. 15 is a fragmentary enlarged sectional view of an organic EL device according to an eighth embodiment of the invention.

### DESCRIPTION OF EXEMPLARY EMBODIMENTS

Embodiments of the invention will now be described with reference to the drawings. For the sake of convenience, the dimensional proportions of parts may differ as needed in the drawings. “Above”, “over”, “below”, “under” and the like in the description are used to express positional relations with respect to the positions shown in the drawings, and the thickness of a layer mentioned herein refers to the dimension of the layer in the vertical direction in the drawings.

### First Embodiment

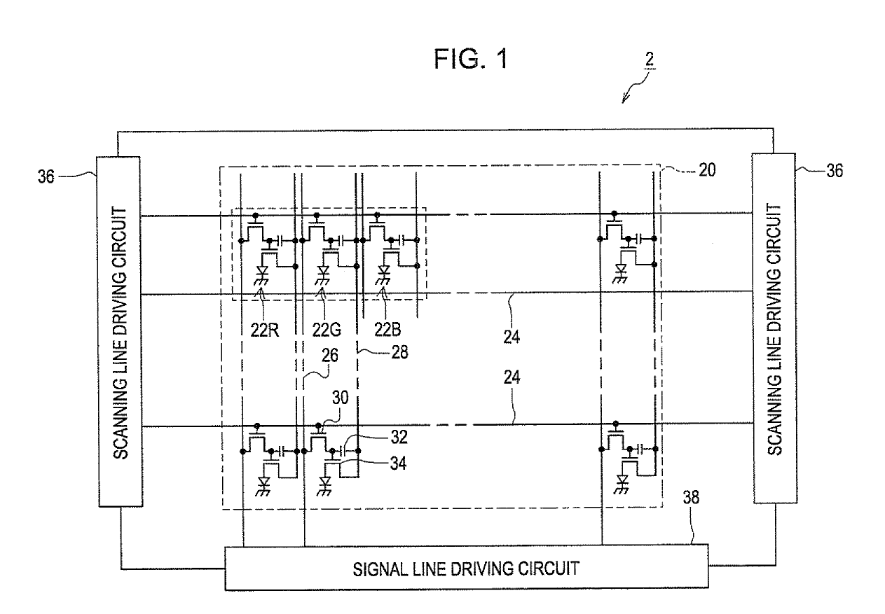

FIG. 1 is an equivalent circuit diagram of an organic EL device 2 according to a first embodiment of the invention. The organic EL device 2 has a display region 20 including red organic EL elements 22R emitting red light, green organic EL elements 22G emitting green light, and blue organic EL elements 22B emitting blue light. These three types of organic EL elements 22 are regularly arranged in the display region. When it is not required that the color of the emitted light be discriminated, each color organic EL element 22 is referred to as simply organic EL element. The three types of organic EL elements 22 are substantially the same except for the organic EL material used as an electrooptic material.

The organic EL device 2 is of an active matrix type forming images in the display region 20 including many organic EL elements 22 by controlling light emission of each organic EL element 22. The display region 20 also includes a plurality of scanning lines 24, a plurality of signal lines 26 orthogonal to the scanning lines 24, and a plurality of power supply lines 28 parallel to the signal lines 26. Each organic EL element 22 is formed in a section surrounded by the scanning lines 24, the signal line 26 and the power supply line 28.

Each pixel region includes a switching TFT (thin film transistor) 30 having a gate electrode to which scanning signals are transmitted through the scanning line 24; a hold capacitor 32 holding an image signal transmitted from the signal line 26 through the switching TFT 30; a driving TFT 34 having a gate electrode to which the image signal held in the hold capacitor 32 is transmitted; and an organic EL element 22 to which a driving current flows from the power supply line 28 through the driving TFT 34. The organic EL element 22 emits light at a luminance according to the magnitude of the current.

Scanning line driving circuits 36 and a signal line driving circuit 38 are disposed around the display region 20. The scanning line driving circuit 36 supplies scanning signals to the scanning lines 24 one after another according to the signal transmitted from an external circuit (not shown). The signal line driving circuit 38 supplies image signals to the signal lines 26.

On bringing the switching TFT 30 into the ON state by driving the scanning line 24, the hold capacitor 32 holds the potential of the signal line 26 at this time, and the level of the driving TFT 34 is determined according to the state of the hold capacitor 32. A driving current flows to the organic EL element 22 from the power supply line 28 through the driving TFT 34, and the organic EL element 22 emits light according to the magnitude of the driving current. Each organic EL element 22 is controlled independently, and an color image is formed in the display region 20 by controlling the luminances of red, green and blue light from the respective organic EL elements 22R, 22G and 22B according to the driving current.

The organic EL device 2 of the present embodiment is a full-color panel using below-described organic EL polymers. The organic EL device 2 includes organic EL elements emitting red light, organic EL elements emitting green light, and organic EL elements emitting blue light in a plane, and thus can display full-color images. The organic EL device 2 is of top emission type that emits light generated in the organic EL elements through the opposite side to the substrate.

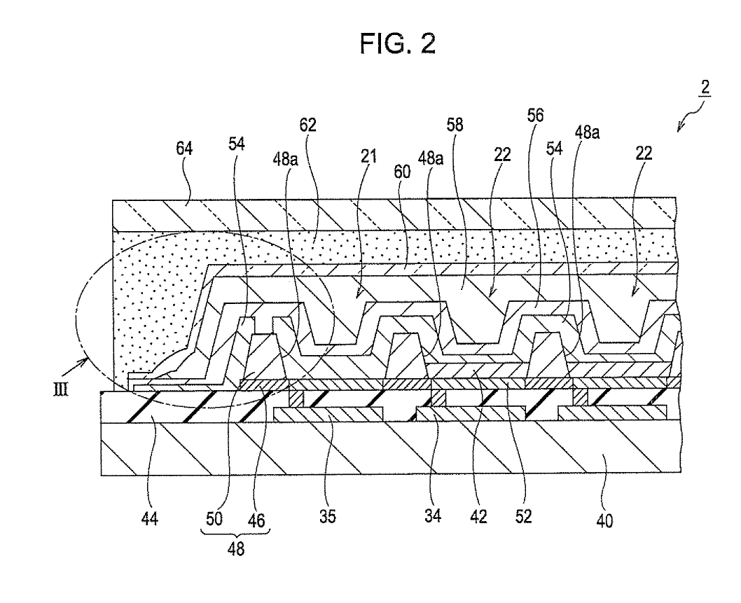

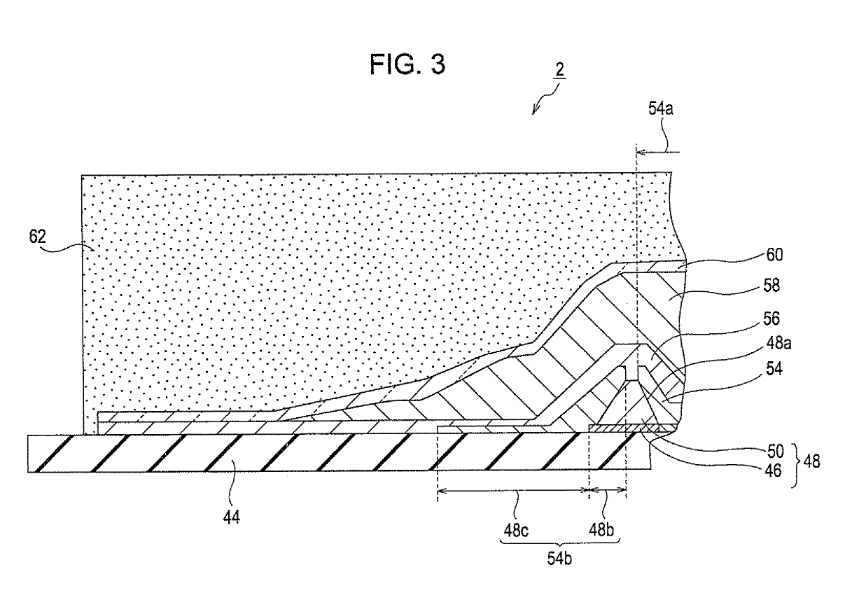

FIG. 2 is a schematic sectional view of the organic EL device 2 of the present embodiment, and FIG. 3 is a fragmentary enlarged sectional view of portion III in FIG. 2. The organic EL device 2 includes a flat substrate 40. The substrate 40 may be made of glass or plastic, and a plurality of organic EL elements 22 are disposed on the surface of the substrate 40. Each organic EL element 22 includes an organic luminescent layer 42 made of an organic EL polymer, which will be described later. When the organic EL element 22 receives a current at a timing at which light is emitted, the organic luminescent layer 42 emits light. The organic EL elements 22 are classified into three types depending on the color of the emitted light. The three types are regularly arranged on the substrate 40.

The substrate 40 has a plurality of driving TFTs 34 and conductor lines (not shown except some lines) thereon corresponding to the respective organic EL elements 22. The driving TFT 34 receives an electric energy and a control signal to drive the corresponding organic EL element 22. More specifically, the driving TFTs 34 supply an electric energy to the respective organic EL elements 22. The driving TFTs 34 are covered with an inorganic insulating layer 44 on the substrate 40. The inorganic insulating layer 44 isolates the driving TFTs 34 and conductor lines from each other, and may be made of, for example, a silicon compound.

A lyophilic bank layer (part of partition structure 48) 46 is formed of silicon dioxide to a thickness of, for example, 50 to 200 nm on the inorganic insulating layer 44, and a lyophobic bank layer (part of partition structure 48) 50 is formed of acrylic resin or polyimide to a thickness of, for example, 1 to 3 μm on the lyophilic bank layer 46. The lyophilic bank layer 46 and the lyophobic bank layer 50 define a plurality of openings 48a corresponding to the positions of the anodes (first electrodes) 52 and thus form a partition structure 48. The inorganic insulating layer 44 and the partition structure 48 define recesses, and the organic EL elements 22 occupy the bottoms of the recesses. The organic luminescent layer 42 is disposed in each of the openings 48a. For a single-color light-emitting device and electronic apparatus, in which the organic luminescent layer is not divided according to the colors to be emitted, an organic luminescent layer 42 is formed so as to extend across the plurality of anodes 52 and the lyophilic bank layer 46 by spin coating or slit coating, without forming the lyophobic bank layer 50.

The organic EL element 22 includes an anode 52 and a common cathode layer (second electrode) 54 with the organic luminescent layer 42 therebetween. The anode 52 and the common cathode layer 54 are electrodes for injecting holes or electrons to the organic luminescent layer 42, and generate an electric field by an electric energy supplied thereto. The anode 52 is formed of a material having a work function of, for example, 5 eV or more and having a high hole injection ability, such as ITO, on the inorganic insulating layer 44. The anode is connected to the corresponding TFT 34 with a conductor line. The common cathode layer 54 is connected to a cathode power supply line 35 in a contact region 21.

The common cathode layer 54 can be made of an alkaline-earth metal alloy. For example, the common cathode layer 54 is formed of a magnesium-silver alloy to a thickness of, for example, 1 to 50 nm, and preferably 10 to 30 nm. The common cathode layer 54 spreads outward from the edge 48b of the partition structure 48, so that the common cathode layer 54 containing an alkaline-earth metal adsorbs moisture penetrating through cracks in a cathode protection layer 56, an organic buffer layer 58 and a gas barrier layer 60 to hinder the water from penetrating the partition structure 48. In addition, the common cathode layer 54 can appropriately reduce or prevent the transfer of oxygen-containing substances, such as moisture and oxygen, from the exterior to the interior of the organic EL device 2. Consequently, the degradation in luminous efficiency and other properties can be favorably reduced or prevented. The common cathode layer 54 has a thickness of at least 1 nm from the viewpoint of being used as the getter while ensuring electron injection ability. However, an extremely large thickness of the common cathode layer 54 may reduce the transmittance to visible light, and result in the degradation of image quality of the organic EL device 2. Thus, the common cathode layer 54 formed as above can function as the getter and enhance the quality of displayed images. By use of an optically transparent material for the common cathode layer 54, a top emission type organic EL device can be achieved, which emits light from the organic luminescent layer 42 through the common cathode layer 54. The common cathode layer 54 is divided into a first portion 54a and a second portion 54b when viewed from above. The first portion 54a covers the organic luminescent layers 42 and the entire partition structure 48 except the edge 48b. The second portion 54b covers the edge 48b of the partition structure and the external region 48c around the partition structure 48. The first portion 54a of the common cathode layer 54 is formed on the organic luminescent layer 42 and the lyophobic bank layer 50 to function as a common electrode extending across the plurality of organic EL elements 22. The first portion 54 includes, for example, an electron injection buffer layer facilitating the injection of electrons to the organic luminescent layer 42 and a low-resistance layer formed of a metal, such as ITO or aluminum, on the electron injection buffer layer. The electron injection buffer layer can be made of, for example, lithium fluoride, metal calcium, or a magnesium-silver alloy.

The first portion 54a and the second portion 54b of the common cathode layer 54 may be in the same layer. Thus, the getter can be formed in the same layer as the common cathode layer 54 on the substrate 40 by only preparing a mask for patterning. The manufacturing process can be simplified and the connection can be easy. For example, an ITO common cathode layer 54 allows easy soldering and has a high adhesion to the sealing resin of the sealing layer.

The second portion 54b of the common cathode layer 54 may spread over the entirety of the outer region of the surface of the substrate 40. Such a structure enhances the deoxidation/dehydration ability. The second portion 54b may be electrically floated. By dividing the common cathode layer 54 into two portions: the second portion 54b spreading outward from the edge 48b of the partition structure 48; and the first portion 54a covering the organic luminescent layers 42 and the entire partition structure 48 except the edge 48b, the second portion 54b can be electrically floated. Wiring is disposed at the end of the substrate 40. If the common cathode layer 54 extends outward beyond the edge 48b of the partition structure 48, a short circuit may occur between the common cathode layer 54 and the wiring. By dividing the common cathode layer 54 into the first portion 54a and the second portion 54b, a short circuit does not occur between the common cathode layer 54 and the wiring even though an electric field is applied to the organic luminescent layers 42.

The organic luminescent layer 42 includes a light-emitting layer that is excited to emit light by recombination of holes and electrons injected by an electric field. The organic luminescent layer 42 may have a multilayer structure including layers other than the light-emitting layer. In this instance, preferably, each layer of the organic luminescent layer 42 has a small thickness of 300 nm or less from the viewpoint of reducing the electric resistance. The layers other than the light-emitting layer include a hole injection layer facilitating hole injection, a hole transport layer facilitating the transport of holes to the luminescent layer, an electron injection layer facilitating electron injection, and an electron transport layer facilitating the transport of electrons to the luminescent layer. These layers help the recombination of holes and electrons.

The light-emitting layer is made of an organic EL polymer. A compound having a relatively high molecular weight is selected as the organic EL polymer from the organic compounds that can emit light by recombination of holes and electrons. The organic EL polymer is selected according to the color of light emitted from the organic EL element 22. The materials of the other layers of the organic luminescent layer 42 helping the recombination are each selected according to the materials of the adjoining layers. If the material of each layer is dissolved in or diluted with a solvent and applied in a pattern by an ink jet method or printing, the surface of the lyophobic bank layer 50 repels the material of the organic luminescent layer 42. Thus, the material of the luminescent layers 42 is deposited for the respective pixels according to the colors. For a single color emission, pixels can be separated from each other even by forming an organic luminescent layer 42 so as to extend across the anodes 52 and the lyophilic bank layer 46 by spin coating or slit coating without forming the lyophobic bank layer 50. The lyophilic bank layer 46 makes the thickness of the organic luminescent layer 42 uniform even at the ends of the anode 52 in the bottom of the recess, and on which the lyophobic bank layer 50 is disposed. The lyophilic bank layer 46 is formed of, for example, silicon dioxide to a thickness of 50 to 200 nm.

The cathode protection layer (sealing layer) 56 is disposed over the inorganic insulating layer 44 and the common cathode layer 54 to cover the common cathode layer 54. In order to planarize the unevenness formed by the presence of the partition structure 48, an organic buffer layer (sealing layer) 58 is formed on the cathode protection layer 56 so as to overlie all the organic EL elements 22. Furthermore, a gas barrier layer (sealing layer) 60 is formed over the cathode protection layer 56 and the organic buffer layer 58 so as to cover the entirety of the organic buffer layer 58 including the ends.

The gas barrier layer 60 enhances the sealing properties to seal the organic buffer layer 58 and the organic EL elements 22, and is in firm contact with the organic buffer layer 58. The gas barrier layer 60 is made of an optically transparent, water-resistant material capable of blocking gases. Preferably, silicon-containing compounds are used, such as silicon oxynitride, silicon nitride and SiNH. The gas barrier layer 60 can be formed by high-density plasma deposition, such as sputtering, ion plating or CVD using inductively coupled plasma (TCP), electron cyclotron resonance plasma ((ECR plasma) or other high-density plasma generated from a plasma gun. High-density plasma deposition can form a high-density, high-quality inorganic film at a low temperature. The thickness of the gas barrier layer 60 is set in view of the sealing properties to seal the organic EL elements 22, the possibility of cracking or separating the gas barrier layer 60, and the manufacturing cost. For example, the gas barrier layer 60 may have a thickness of 300 to 800 nm.

The organic buffer layer 58 is intended to enhance the flatness and adhesion of the gas barrier layer 60 and alleviate the stress in the gas barrier layer 60. The organic buffer layer 58 can be formed by screen printing of a material (liquid) having a specific viscosity and composition (described below) in an atmosphere of reduced pressure, using a screen mesh and a squeegee to control the thickness thereof so as to reduce the unevenness formed by the presence of the partition structure 48, followed by curing.

The cathode protection layer 56 is intended to protect the common cathode layer 54 and enhance the wettability and adhesion of the organic buffer layer 54 before being cured. The cathode protection layer 56 is made of an adhesive, optically transparent and water-resistant silicon compound. For the top emission type, the common cathode layer 54 tends to be formed thin in view of the transparency, and accordingly, the incidence of pinholes is increased. Consequently, a trace amount of moisture trapped during transport before forming the organic buffer layer 58, and the constituents of the organic buffer layer 58 before curing can penetrate to organic luminescent layers 42 to damage. The damage of the organic luminescent layer 42 causes dark spots. The cathode protection layer 56 prevents such problems. Accordingly, the cathode protection layer 56 has a thickness of 100 nm or more. In addition, since there are elevations on the upper surface of the common cathode layer 54 due to the presence of the lyophobic bank layer 50 and the organic EL elements 22, stress concentration occurs in the cathode protection layer 56. From the viewpoint of preventing fracture resulting from the stress concentration, the cathode protection layer 56 has a thickness of 200 nm or less.

An adhesive layer (sealing layer) 62 is formed over the substrate 40 to cover the inorganic insulating layer 44, the cathode protection layer 56 and the gas barrier layer 60. The entire adhesive layer 62 is covered with a surface protection member (sealing member) 64. The lower surface of the surface protection member 64 is fully in contact with the adhesive layer 62. The adhesive layer 62 bonds the surface protection member 64 to the substrate 40, and is made of an optically transparent resin adhesive. The resin adhesive contains, for example, epoxy resin, acrylic resin, urethane resin, silicone resin, or the like. The surface protection member 64 is intended to protect the optical properties and the gas barrier layer, and is made of glass or an optically transparent plastic. Examples of such a plastic include polyethylene terephthalate, acrylic resin, polycarbonate and polyolefin. The surface protection member 64 may have a function as a color filter, or the function of blocking or absorbing UV light, preventing the reflection of external light, or dissipating heat. If the optical functions, such as color filters, are not needed, only the adhesive layer 62 may be provided without forming the surface protection member 64 in view of the cost efficiency.

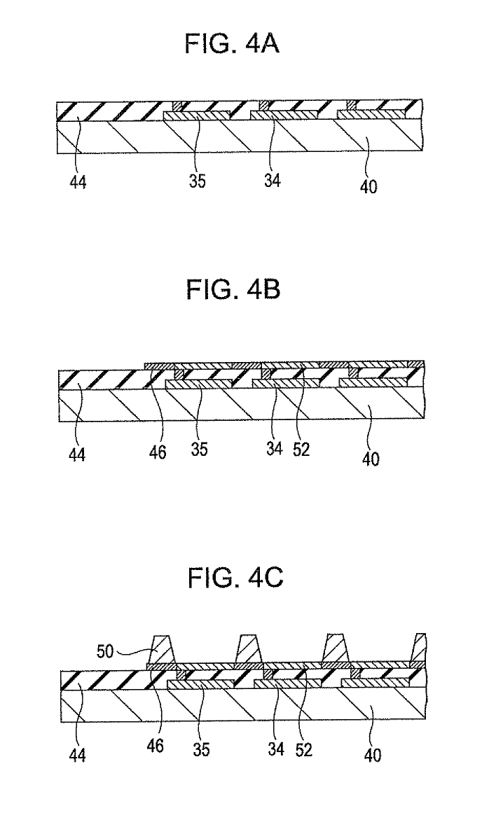

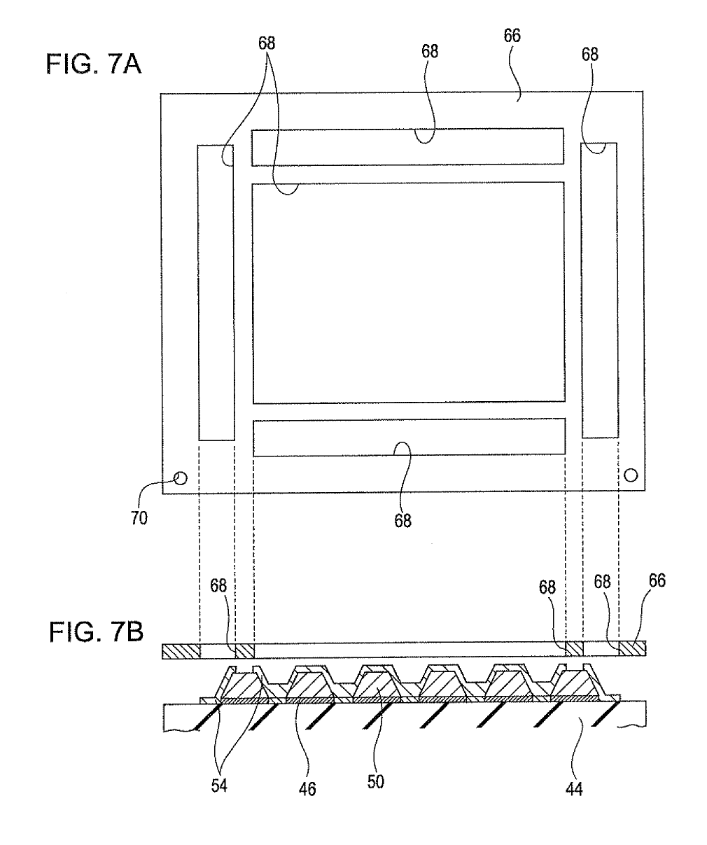

The manufacture of the organic EL device 2 of the present embodiment will now be described with reference to the related drawings. FIGS. 4A to 6C are sectional views showing a manufacturing process of the organic EL device 2 of the present embodiment. FIG. 7A is a plan view of a mask member used in the manufacturing process of the present embodiment, and FIG. 7B is a sectional view of the organic EL device 2 corresponding to the mask member shown in FIG. 7A.

In manufacture of the organic EL device 2 of the present embodiment, first, the driving TFTs 34, conductor lines and the inorganic insulating layer 44 are formed on the substrate 40, as shown in FIG. 4A. Then, the anodes 52 are formed on the inorganic insulating layer 44, as shown in FIG. 4B, by depositing a light-reflective material, such as an aluminum-copper alloy, and transparent ITO by sputtering. The anodes 52 are thus connected to the driving TFTs 34 controlling the on/off state. Subsequently, a lyophilic bank layer 46 is formed on the inorganic insulating layer 44 so as to surround the anodes 52. Turning to FIG. 4C, a lyophobic bank layer 50 is formed of an organic compound such as polyimide or acrylic resin on the lyophilic bank layer 46. The resulting structure is subjected to plasma cleaning or other cleaning to remove organic foreign matter from the substrate 40 and enhance the wettability of the ITO surfaces.

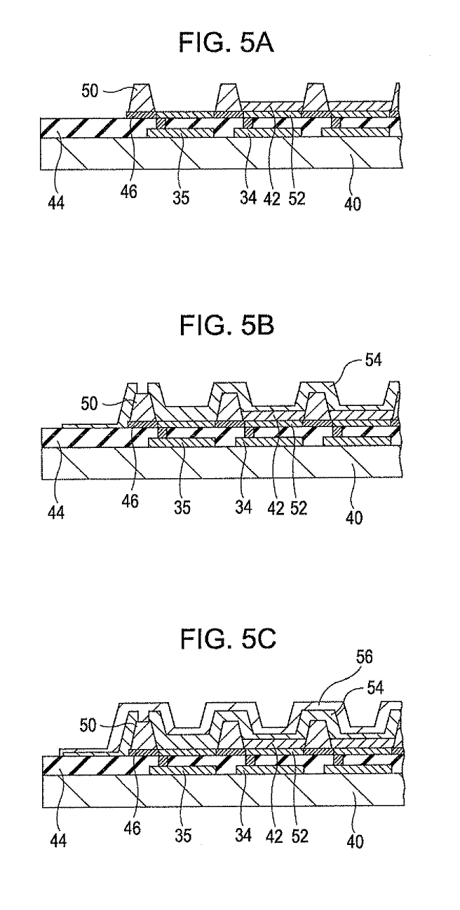

Turning now to FIG. 5A, the organic luminescent layers 42 are formed on the respective anodes 52. The material of the organic luminescent layer 42 spreads uniformly along the anodes 52 and the lyophilic bank layer 46. Thus, the resulting organic luminescent layer 42 can be uniform and flat. For forming the light-emitting layer of the organic luminescent layer 42, an organic EL polymer for emitting red light is applied onto the anodes 52 of the organic EL elements 22 emitting red light 52. The same applies for the organic EL elements 22 emitting green light and the organic EL elements 22 emitting blue light. The material of the light-emitting layers can be applied by spin coating or slit coating. If three-color light-emitting layers are formed separately, an ink jet method or screen printing may be applied to form a pattern corresponding to each pixel. These methods allow material-efficient coating. If the organic luminescent layer 42 includes a plurality of layers, these layers are formed one after another.

Turning to FIG. 5E, the common electrode, or common cathode layer 54, is formed for the organic EL elements 22. The common cathode layer 54 is formed of a magnesium-silver alloy, which is an alkaline-earth metal alloy. More specifically, first, a metal or metal compound having high electron injection ability, such as lithium fluoride, is deposited through the mask member 66 shown in FIG. 7A by vacuum vapor deposition using a heating board (crucible). Then, a metal or alloy having a low work function, such as magnesium-silver alloy or other alkaline-earth metal alloy, is deposited to form a thin layer by vacuum vapor deposition. The common cathode layer 54 is thus formed thin from the viewpoint of increasing the conductivity and the optical transparency as much as possible and reducing the reflectivity. Thus, the light emitted upward (in the direction opposite to the substrate 40) from the organic luminescent layers 42 can be irradiated to the outside as directly as possible so that the resulting organic EL device can be an efficient top emission type.

By use of an optically transparent material for the common cathode layer 54, the organic EL device 22 of the present embodiment can be of top emission type, which emits light from the organic luminescent layer 42 through the common cathode layer 54.

Although the common cathode layer 54 is made of a magnesium-silver alloy in the present embodiment, the material of the common cathode layer 54 can be selected from the substances capable of reacting with water and oxygen to produce a hydroxide and an oxide without being limited to magnesium-silver alloys. Such substances include alkaline-earth metals, such as Be, Mg, Ca, Sr, and Ba, and alkali metals, such as Li, Na, K, Rb, and Cs. For forming a layer containing an alkaline-earth metal or alkali metal on the substrate, for example, vacuum vapor deposition, sputtering, or CVD can be used.

Alternatively, substances capable of physically taking water and oxygen molecules in or adsorbing those molecules may be used. Such substances include molecular sieves having a zeolite structure and silica gel.

The second portion 54b (see FIG. 3) of the common cathode layer 54 may be formed simultaneously with the first portion 54a (see FIG. 3). In this instance, the second portion 54b is formed thicker than the first portion 54a. For example, first, deposition is performed for both the first portion 54a and the second portion 54b through a mask member 66 having a pattern corresponding to the first and second portions 54a and 54b for a time period for which the first portion 54a can have a desired thickness, and then only the second portion 54b is further deposited through a second portion-specific mask (not shown).

### Mask Member

As shown in FIG. 7A, the mask member 66 has patterned openings 68, and alignment marks 70 used for being placed on a substrate to be subjected to vapor deposition. The mask member 66 has an area substantially equal to the surface area of the substrate of the organic EL device 2. The mask member 66 is made of (110)-plane oriented silicon (single crystal silicon). Consequently, the difference in thermal expansion coefficient can be reduced to prevent the mask member 66 from being deformed by thermal expansion or bending.

The openings 68 are formed corresponding to the pattern to be formed on the substrate by vapor deposition, and through which the vapor deposition material from a deposition source is deposited on the substrate. For example, the openings 68 pass through the thickness of the mask member 66, and include a rectangular opening in the middle of the mask member 66 and strip-shaped openings along the four sides, as shown in FIG. 7A. The mask member 66 is disposed in such a manner that the outermost lines of the partition structure 48 are located between the rectangular opening in the middle and the strip-shaped openings, as shown in FIG. 7B.

Further, there are two alignment marks 70 in regions not having the openings in corners of the mask member 66. This arrangement of the alignment marks 70 allows precise alignment with the substrate to be subjected to vapor deposition. The alignment marks 70 are located at both ends of a side of the mask member 66 in FIG. 7A, but may be located at both ends of a diagonal of the mask member 66. The diagonal arrangement of the alignment marks 70 allows more precise alignment. As with the openings 68, the alignment masks 70 may pass through the thickness of the mask member 66. The alignment marks 70 are formed in the same step with the openings 68. The openings 68 may double as alignment marks if the alignment marks are defined by through-holes. In other words, part of the openings 68 may be used as alignment marks 70.

Turning now to FIG. 5C, the common cathode layer 54 is subjected to oxygen plasma treatment, and the cathode protection layer 56 is formed of silicon oxynitride to cover the common cathode layer 54 by high-density plasma deposition, such as ECR sputtering or ion plating. The oxygen plasma treatment is applied to enhance the adhesion between the common cathode layer 54 and the cathode protection layer 56.

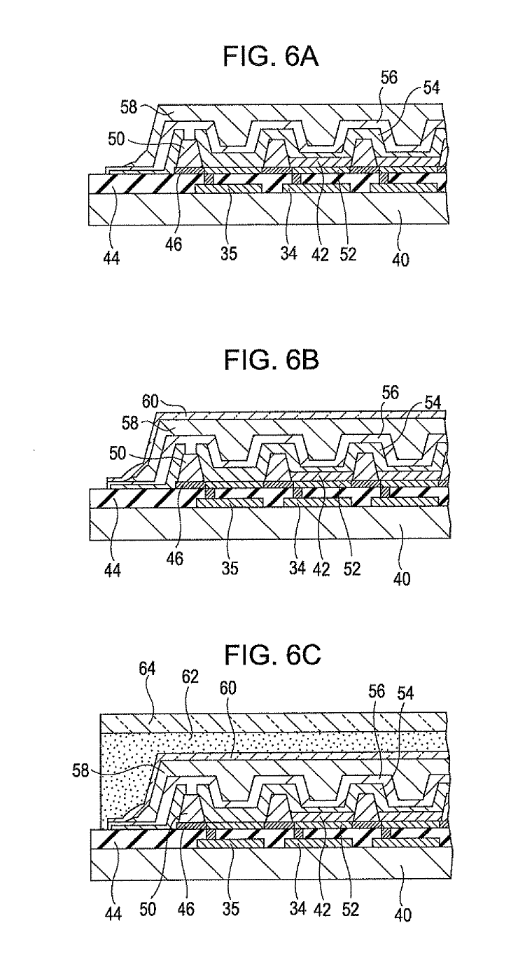

Turning to FIG. 6A, a liquid organic buffer layer material having a viscosity of 2000 to 10000 mPa·s at room temperature (25° C.) is applied onto the cathode protection layer 56 by screen printing in an atmosphere of reduced pressure. After introducing nitrogen gas to return to the atmospheric pressure, the work including the substrate is placed in a curing room and is heated to cure the organic buffer layer material at a temperature of 60 to 100° C. Thus, an organic buffer layer 58 is formed. The reason why this step is performed in an atmosphere of reduced pressure is to remove air bubbles produced during coating with the material and to remove moisture as much as possible. The organic buffer layer material is applied at a relatively low vacuum of 100 to 5000 Pa different from the case of forming the common cathode layer 54 and the cathode protection layer 56. In addition, the atmosphere is purged with nitrogen, so that moisture can be removed until the dew point is reduced to −60° C. or less. The reason why the organic buffer layer material has a viscosity of 2000 mPa·s or more at room temperature is to prevent the organic buffer layer material from penetrating the cathode protection layer 56 to enter the common cathode layer 54 and the organic luminescent layer 42.

The main constituent (for example, in a content of 70% by weight or more) in the organic buffer layer material may be an organic compound having a high fluidity before being cured and not containing a volatile component like a solvent. The present embodiment uses an epoxy monomer (molecular weight: 1000 or less) or oligomer (molecular weight: 1000 to 3000) containing epoxy groups and having a molecular weight of 3000 or less. Examples of such a compound include bisphenol A epoxy oligomer, bisphenol F epoxy oligomer, phenol novolak epoxy oligomer, 3,4-epoxy cyclohexenylmethyl-3′,4′-epoxy cyclohexenecarboxylate, and ε-caprolactone-modified 3,4-epoxy cyclohexylmethyl 3′,4′-epoxy cyclohexanecarboxylate. These compounds may be used singly or in combination.

The organic buffer layer material may contain a curing agent that can react with epoxy monomer or oligomer. The curing agent preferably helps form a strong cured coating exhibiting high electric insulation and high heat resistance, and may be an addition polymerization type having high optical transparency and reducing the variation in curing. For example, the curing agent can be an acid anhydride curing agent, such as 3-methyl-1,2,3,6-tetrahydrophthalic anhydride, methyl-3,6-endomethylene-1,2,3,6-tetrahydro phthalic anhydride, 1,2,4,5-benzene tetracarboxylic dianhydride, 3,3′,4,4′-benzophenone tetracarboxylic dianhydride, or their polymer. The first reason why such a curing agent is used is that the curing using an acid anhydride curing agent is performed at temperatures in the range of 60 to 100° C. and forms a cured polymer coating containing ester bonds having high adhesion to silicon oxynitride. The second reason is that acid anhydride curing agents allow low-temperature, short-time curing by combined use of a curing accelerator promoting the ring opening of the anhydride, such as aromatic amine, alcohol, amino phenol or other compounds having relatively high molecular weights. The third reason is that acid anhydride curing agents do not cause rapid curing shrinkage more than cationic photopolymerization initiators and accordingly do not easily damage other members.

The organic buffer layer material may further contain a silane coupling agent enhancing the adhesion to the common cathode layer 54 or the gas barrier layer 60, a water scavenger such as an isocyanating compound, or other additives such as particles for preventing curing shrinkage. These additives before curing preferably have viscosities of 1000 to 10000 mPa·s at room temperature.

Preferably, the main constituent and other additives in the organic buffer layer material have each a viscosities of 1000 mPa·s or more before curing. Such a viscosity can prevent the organic buffer layer material before being cured from penetrating the organic luminescent layer 42. The viscosity of the material should be determined from the viewpoint of forming a pattern to a desired thickness with a desired accuracy, and of preventing the occurrence of air bubbles in the resulting layer.

Turning now to FIG. 6B, the organic buffer layer 58 is subjected to oxygen plasma treatment in an atmosphere of reduced pressure, and the gas barrier layer 60 is formed to fully cover the entire organic buffer layer 58 including the ends by high-density plasma deposition, such as ECR sputtering or ion plating. The oxygen plasma treatment is applied to enhance the adhesion between the organic buffer layer 58 and the gas barrier layer 60.

Subsequently, an optically transparent resin adhesive is applied to cover the inorganic insulating layer 44, the cathode protection layer 56, and the gas barrier layer 60, and a surface protection member 64 is disposed on the resin adhesive in such a manner that the lower surface of the surface protection member 64 fully comes in contact with the resin adhesive, as shown in FIG. 6C. The resin adhesive is then cured to form an adhesive layer 62. As an alternative to the resin adhesive, a liquid adhesive may be used, or the inorganic insulating layer 44 and the surface protection member 64 may be bonded by disposing an adhesive sheet therebetween and then compressing the adhesive sheet.

In the organic EL device of the present embodiment, the common cathode layer 54 is disposed outward from the edge 48b of the partition structure 48, so that the common cathode layer 54 adsorbs moisture penetrating through cracks in the cathode protection layer 56, the organic buffer layer 58 and the gas barrier layer 60 to hinder the moisture from penetrating the partition structure 48. In addition, the thickness of the common cathode layer 54 is generally several tens of nanometers, and does not increase the frame width. Accordingly, the structure of the common cathode layer 54 can enhance the moisture resistance while reducing the width of the frame.

### Second Embodiment

The organic EL device according to a second embodiment includes the organic buffer layer having the same structure as the common cathode layer in the first embodiment. The organic EL device of the second embodiment is a full color display panel using a low-molecular-weight organic EL material described below, and includes organic EL elements emitting white light and color filters for displaying full color images.

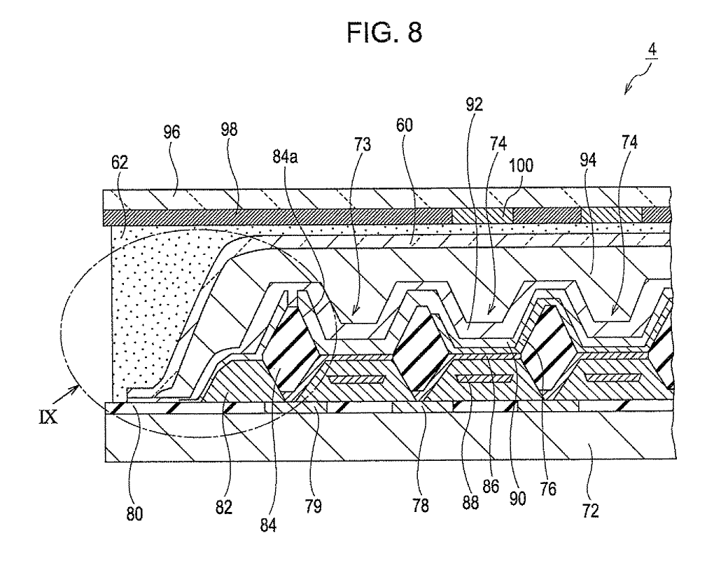

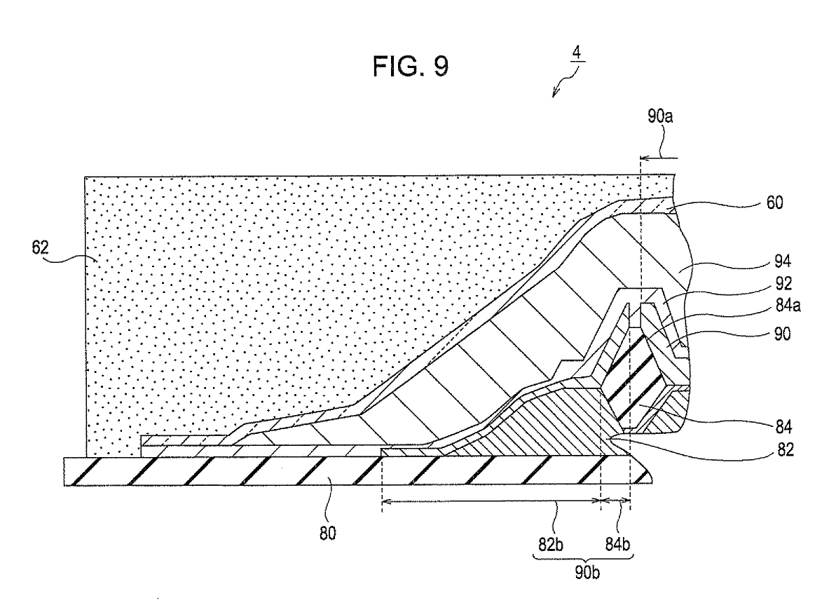

FIG. 8 is a schematic sectional view of an organic EL device 4 according to the second embodiment, and FIG. 9 is a fragmentary enlarged sectional view of portion IX in FIG. 8. The organic EL device 4 includes a flat substrate 72. The substrate 72 may be made of glass or plastic, and a plurality of organic EL elements 74 are disposed on the surface of the substrate 40. Each organic EL element 74 emits white light and includes an organic luminescent layer 76 containing a low-molecular-weight organic EL material described below. The organic luminescent layer 79 receives an electric energy to emit light.

The substrate 72 has a plurality of TFTs 78 and conductor lines (not shown) thereon corresponding to the respective organic EL elements 74. The TFTs 78 drive the respective organic EL elements 22 in the same manner as the driving TFTs 34 of the first embodiment. The TFTs 78 are covered with an inorganic insulating layer 80. The inorganic insulating layer 80 isolates the TFTs 78 and conductor lines from each other, and may be made of, for example, silicon nitride.

A planarizing layer 82 is formed to eliminate the elevations formed by the presence of the conductor lines and TFTs 78, and a pixel partition insulating layer 84 is formed of an organic compound, such as polyimide or acrylic resin, so as to rise from the bottom of recesses of the planarizing layer 82. The level of the top end of the pixel partition insulating layer 84 lies higher than the top of the planarizing layer 82, and thus the planarizing layer 82 and the pixel partition insulating layer 84 form recesses. The planarizing layer 82 includes metal reflection films 88 reflecting light coming from the respective organic EL elements 74 through the anodes (first electrodes) 86. The metal reflection films 88 are made of a light-reflective metal. An inorganic insulating film (not shown) preventing corrosion is disposed at the bottom of each recess over the metal reflection films 88, and anodes 86 made of ITO having a high work function are disposed on the respective inorganic insulating layers. The planarizing layer 82 and the pixel partition insulating layer 84 define a plurality of openings 84a, thus forming a partition structure. Each organic EL element 74 includes the anode 86 and a common cathode layer (second electrode) 90 with an organic luminescent layer 76 therebetween. The anode 86 and the common cathode layer 90 are electrodes for injecting holes or electrons to the organic luminescent layer 76. The anode 86 is an optically transparent electrode formed of a thin metal, such as aluminum, or ITO on the planarizing layer 82, and is connected to the corresponding TFT 78 through a gap between the planarizing layer 82 and the pixel partition insulating layer 84.

The common cathode layer 90 can be made of an alkaline-earth metal alloy. For example, the common cathode layer 54 is formed of magnesium-silver alloy to a thickness of, for example, 1 to 50 nm, and preferably 10 to 30 nm. The common cathode layer 90 spreads outward from the edge 84b of the pixel partition insulating layer 84, so that the common cathode layer 90 containing an alkaline-earth metal adsorbs moisture penetrating through cracks in the cathode protection layer 92, the organic buffer layer 94 and the gas barrier layer 60 to hinder the moisture from penetrating the partition structure. In addition, the common cathode layer 90 can appropriately reduce or prevent the transfer of oxygen-containing substances, such as moisture and oxygen, from the exterior to the interior of the organic EL device 4. Consequently, the degradation in luminous efficiency and other properties can be favorably reduced or prevented. The common cathode layer 90 has a thickness of at least 1 nm from the viewpoint of being used as the getter while ensuring electron injection ability. However, an extremely large thickness of the common cathode layer 90 may reduce the transmittance to visible light, and result in the degradation of image quality of the organic EL device 4. Thus, the common cathode layer 90 formed as above can function as the getter and enhance the quality of displayed images. By use of an optically transparent material for the common cathode layer 90, a top emission type organic EL device can be achieved, which emits light from the organic luminescent layer 76 through the common cathode layer 90. The common cathode layer 90 is divided into a first portion 90a and a second portion 90b when viewed from above. The first portion 90a covers the organic luminescent layer 76 and the entire partition structure except the outer portion from the edge 84b of the pixel partition insulating layer 84. The second portion 90b covers the edge 84b of the pixel partition insulating layer 84 and at least part of the outer portion 82b of the planarizing layer 82 (covers the edge of the partition structure and at least part of the outer portion of the partition structure). The first portion 90a of the common cathode layer 90 is formed on the organic luminescent layer 76 and the pixel partition insulating layer 84 to function as a common electrode for the organic EL elements 74. The first portion 90a includes, for example, an electron injection buffer layer facilitating the injection of electrons to the organic luminescent layer 76, and an ITO layer on the electron injection buffer layer or a low-resistance layer formed of aluminium or the like in a pattern in a non-pixel region. The electron injection buffer layer can be made of, for example, lithium fluoride or a magnesium-silver alloy.

The first portion 90a and the second portion 90b of the common cathode layer 90 may be in the same layer. Thus, the getter can be formed in the same layer as the common cathode layer 90 on the substrate 72 by only preparing a mask for patterning. The manufacturing process can be simplified and the connection can be easy. For example, an ITO common cathode layer 90 allows easy soldering and has a high adhesion to the sealing resin of the sealing portion.

The second portion 90b of the common cathode layer 90 may spread over the entirety of the outer region of the surface of the substrate 72. Such a structure enhances the deoxidation/dehydration ability. The second portion 90b may be electrically floated. By dividing the common cathode layer 90 into two portions: the second portion 90b spreading outward from the edge 84b of the partition structure; and the first portion 90a covering the organic luminescent layer 76 and the entire partition structure except the outer portion from the edge of the partition structure, the second portion 90b can be electrically floated. Wiring is disposed at the end of the substrate 72. If the common cathode layer 90 extends outward beyond the edge 84b of the pixel partition insulating layer 84 or partition structure, a short circuit may occur between the common cathode layer 90 and the wiring. By dividing the common cathode layer 90 into the first portion 90a and the second portion 90b, a short circuit does not occur between the common cathode layer 90 and the wiring even though an electric field is applied to the organic luminescent layer 76.

The organic luminescent layer 76 corresponds to the organic luminescent layers 42 of the first embodiment. The differences between them are that the organic luminescent layer 76 of the present embodiment is a layer common to the plurality of organic EL elements, and that the light-emitting layer is made of a low-molecular weight organic EL material. The low-molecular-weight organic EL material has a relatively low molecular weight and is selected from the organic compounds that can emit light by recombination of holes and electrons. For example, the low-molecular-weight organic EL material may be styryl amine (host) doped with an anthracene dye (dopant), or styryl amine (host) doped with rubrene dye (dopant). If the organic luminescent layer 76 includes other layers helping the recombination of holes and electrons, the materials of those layers are each selected according to the materials of the adjoining layers. For example, if the organic luminescent layer 76 includes a hole injection layer, it may be made of a triarylamine (ATP) multimer. For a hole transport layer, a triphenyldiamine (TPD) compound may be used. If the organic luminescent layer 79 includes an electron injection layer, it may be made of an aluminum quinolinol complex.

The cathode protection layer (sealing layer) 92 is disposed over the inorganic insulating layer 80 and the common cathode layer 90 to cover the common cathode layer 90 and the planarizing layer 82. An organic buffer layer (sealing layer) 94 is formed on the cathode protection layer 92 to cover all of the organic EL elements 74, the pixel partition insulating layer 84 and the planarizing layer 82. The organic buffer layer 94 is covered with a gas barrier layer 60 over the cathode protection layer 92.

An adhesive layer 62 is formed to cover the inorganic insulating layer 80, the cathode protection layer 92 and the gas barrier layer 60. The entire adhesive layer 62 is covered with a color filter substrate 96. The lower surface of the color filter substrate 96 is fully in contact with the adhesive layer 62. The color filter substrate 96 selectively extracts red light, green light, and blue light from the light emitted from the organic EL elements 74, and includes a black matrix layer 98 having a low optical transparency and filter films 100 covering the openings formed in the black matrix layer 98. The black matrix layer 98 has a plurality of openings, and the filter films include three types: one transmitting only red light; another transmitting only green light; and the other transmitting only blue light. The filter films 100 respectively overlie the organic EL elements 74 and allow the transmission of the respective color light components. The color filter substrate 96 is also intended to protect the gas barrier layer 60, and the region other than the black matrix layer 98 and the filter films 100 is made of glass or an optically transparent plastic. Examples of such a plastic include polyethylene terephthalate, acrylic resin, polycarbonate and polyolefin. The color filter substrate 96 may have the functions of blocking or absorbing UV light, of preventing the reflection of external light, and of dissipating heat.

In manufacture of the organic EL device 4 according to the present embodiment, first, the TFTs 78, conductor lines and the inorganic insulating layer 80 are formed on the substrate 72. Subsequently, the planarizing layer 82 and the metal reflection films 88 are formed on the inorganic insulating layer 80. In order to prevent the corrosion of the metal reflection films 88, the surface of the metal reflection films 88 and their surroundings are covered with an inorganic insulating layer. Then, a plurality of anodes are formed 86. Thus, the TFTs 78 and the anodes 86 are respectively connected to each other. For forming the anodes 86, a known method can be selected according to the material of the anodes 86. Subsequently, the pixel partition insulating layer 84 is patterned using, for example, polyimide on the planarizing layer 82 and part of the anodes 86. The resulting substrate 72 is subjected to cleaning, such as plasma cleaning, to remove organic foreign matter and increase the work function.

Then, the organic luminescent layer 76 common to the plurality of organic EL elements 74 is formed on the exposed anodes 86. The light-emitting layer of the organic luminescent layer 76 is formed of a low-molecular-weight organic EL material. The organic luminescent layer is formed by vacuum vapor deposition using a heating board. This method is applied regardless of whether the organic luminescent layer 76 is constituted of only the light-emitting layer or of a plurality of layers. If the organic luminescent layer 76 includes a plurality of layers, these layers are formed one after another.

Subsequently, the common cathode layer 90 common to the plurality of organic EL elements 74 is formed. The common cathode layer 90 may be formed of a magnesium-silver alloy, which is an alkaline-earth metal alloy. More specifically, first, a metal or metal compound having high electron injection ability, such as lithium fluoride, is deposited through the mask member 66 shown in FIG. 7A by vacuum vapor deposition using a heating board (crucible). Then, a metal or alloy having a low work function, such as magnesium-silver alloy or other alkaline-earth metal alloy, is deposited to form a thin layer by vacuum vapor deposition. The common cathode layer 90 is thus formed thin from the viewpoint of increasing the conductivity and the optical transparency as much as possible and reducing the reflectivity. Thus, the light emitted upward (in the direction opposite to the substrate 72) from the organic luminescent layer 76 can be irradiated to the outside as directly as possible so that the resulting organic EL device can be an efficient top emission type.

By use of an optically transparent material for the common cathode layer 90, the organic EL device 74 of the present embodiment can be of top emission type, which emits light from the organic luminescent layer 76 through the common cathode layer 90.

Although the common cathode layer 90 is made of a magnesium-silver alloy in the present embodiment, the material of the common cathode layer 54 can be selected from the substances capable of reacting with water and oxygen to produce a hydroxide and an oxide without being limited to magnesium-silver alloys. Such substances include alkaline-earth metals, such as Be, Mg, Ca, Sr, and Ba, and alkali metals, such as Li, Na, K, Rb, and Cs. For forming an alkaline-earth metal or alkali metal layer on the substrate, for example, vacuum vapor deposition, sputtering, or CVD can be used.

Alternatively, substances capable of physically taking water and oxygen molecules in or adsorbing those molecules may be used. Such substances include molecular sieves having a zeolite structure and silica gel.

The second portion 90b (see FIG. 9) of the common cathode layer 90 may be formed simultaneously with the first portion 90a (see FIG. 9). In this instance, the second portion 90b is formed thicker than the first portion 90a. For example, first, deposition is performed for both the first portion 90a and the second portion 90b through a mask member 66 having a pattern corresponding to the first and second portions 90a and 90b for a time period for which the first portion 90a can have a desired thickness, and then only the second portion 90b is further deposited through a second portion-specific mask (not shown).

Subsequently, oxygen plasma treatment is performed. Then, the cathode protection layer 92 is formed to cover the common cathode layer 90. The organic buffer layer 94 is formed on the cathode protection layer 92 by screen printing in an atmosphere of reduced pressure. After oxygen plasma treatment is performed, the gas barrier layer 60 is formed to cover the organic buffer layer 94.

Subsequently, an optically transparent resin adhesive is applied to cover the inorganic insulating layer 80, the cathode protection layer 92, and the gas barrier layer 60, and a color filter substrate 96 is disposed on the resin adhesive in such a manner that the lower surface of the color filter substrate 96 fully comes in contact with the resin adhesive. The resin adhesive is then cured to form the adhesive layer 62. In this instance, the resin adhesive is cured in a state where each filter film 100 of the color filter substrate 96 overlies the corresponding organic EL element 74. The color filter substrate 96 may be bonded in other manners as described for the surface protection member 64 in the first embodiment.

The organic EL device 4 according to the second embodiment can produce the same effects as the organic EL device 2 according to the first embodiment.

### Third Embodiment

An organic EL device according to a third embodiment of the present invention is the same as the organic EL device 2 of the first embodiment except for the structure of the organic buffer layer.

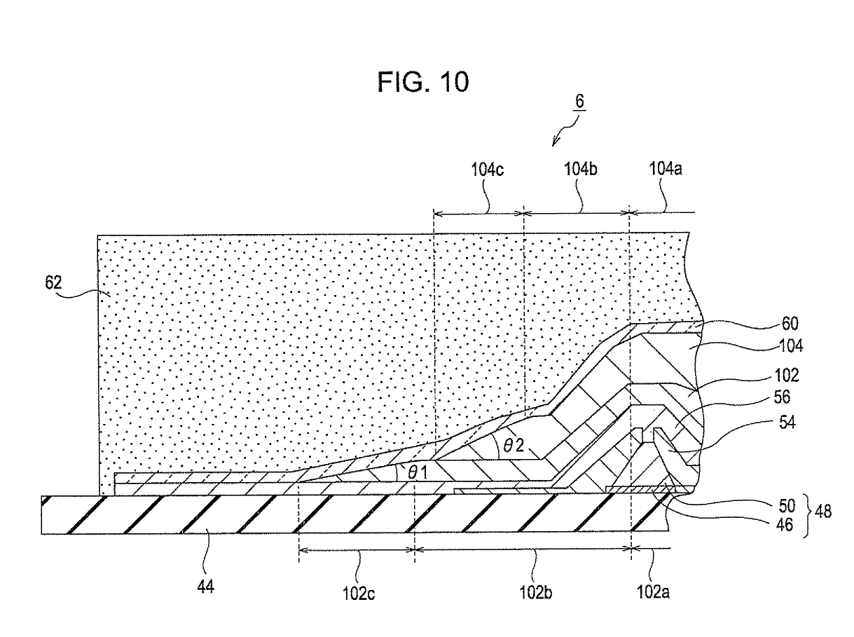

FIG. 10 is a fragmentary enlarged sectional view of an organic EL device 6 according to the third embodiment. The organic EL device 6 of the present embodiment has a first organic buffer layer 102 formed on the cathode protection layer 56 so as to overlie all the organic EL elements 22. The first organic buffer layer 102 thus planarize the unevenness formed by the presence of the partition structure 48. A second organic buffer layer 104 is formed on the first organic buffer layer 102 so as to overlie all the organic EL elements 22. A gas barrier layer 60 is formed over the cathode protection layer 56, the first organic buffer layer 102 and the second organic buffer layer 104 to fully cover the entirety of the first and second organic buffer layers 102 and 104 including their ends.

The gas barrier layer 60 is intended to enhance the sealing properties to seal the first organic buffer layer 102, the second organic buffer layer 104 and the organic EL elements 22, and is in firm contact with the first and second organic buffer layers 102 and 104. The gas barrier layer 60 is made of an optically transparent, water-resistant material capable of blocking gases. Preferably, silicon-containing compounds are used, such as silicon oxynitride, silicon nitride and SiNH. The gas barrier layer 60 can be formed by high-density plasma deposition, such as sputtering, ion plating or CVD using inductively coupled plasma (ICP), electron cyclotron resonance plasma ((ECR plasma) or other high-density plasma generated from a plasma gun. High-density plasma deposition can form a high-density, high-quality inorganic film at a low temperature. The thickness of the gas barrier layer 60 is set in view of the sealing properties to seal the organic EL elements 22, the possibility of cracking or separating the gas barrier layer 60, and the manufacturing cost. For example, the gas barrier layer 60 may have a thickness of 300 to 800 nm.

The first organic buffer layer 102 and the second organic buffer layer 104 are intended to enhance the flatness and adhesion of the gas barrier layer 60 and alleviate the stress in the gas barrier layer 60. The organic buffer layers 102 and 104 can be formed by screen printing of a material (liquid) having a specific viscosity and composition (described below) in an atmosphere of reduced pressure, using a screen mesh and a squeegee to control the thickness thereof so as to reduce the unevenness formed by the presence of the partition structure 48, followed by curing. The region over the substrate 40 covered with the first organic buffer layer 102 includes the region over the substrate 40 covered with the second organic buffer layer 104.

Preferably, the first organic buffer layer 102 has a thickness of 3 to 10 μm and includes a first coating portion 102a overlying all the organic EL elements 22, a first constant thickness portion 102b surrounding the first coating portion 102a, and a first outer portion 102c surrounding the first constant thickness portion 102b and whose thickness is gradually reduced outward. Since the first organic buffer layer 102 is formed by applying a liquid material, the angle θ1 between the upper surface of the first outer portion 102c and the upper surface of the substrate 40 depends on the thickness of the first constant thickness portion 102b. In the present embodiment, the upper limit of the thickness of the first constant thickness portion 102b is specified. Consequently, the upper surface of the first coating portion 102a is not flat.

Preferably, the second organic buffer layer 104 has a thickness of 3 to 20 μm according to the height of the partition structure 48, and includes a second coating portion 104a overlying all the organic EL elements 22, a second constant thickness portion 104b surrounding the second coating portion 104a, and a second outer portion 104c surrounding the second constant thickness portion 104b and whose thickness is gradually reduced outward. The second organic buffer layer 104 is formed by applying a liquid material, and the application of the liquid material is performed so that the upper surface of the second coating portion 104a becomes flat. Accordingly, the second constant thickness portion 104b has a larger thickness than the first constant thickness portion 102b, and the angle θ2 between the upper surface and the lower surface of the second outer portion 104c is larger than the angle θ1. The thicknesses of the first organic buffer layer 102 and the second organic buffer layer 104 are set in view of the ability to block foreign matter penetrating through the gas barrier layer and the percentage of light deviating to the sides of the surface protection member 64 (see FIG. 2, described below) and the sides of the adhesive layer 62 (described below) without reaching the upper surface of the surface protection member 64.

The organic EL device 6 according to the third embodiment can produce the same effects as the organic EL device 2 according to the first embodiment.

In addition, since the organic EL device 6 of the present embodiment has two organic buffer layers, the thickness each organic buffer layer can be smaller than that of a single layer organic buffer layer. Accordingly, the end of each organic buffer layer can have a smaller angle than the end of the single layer organic buffer layer. For example, the first outer portion 102c of the lower and wider first organic buffer layer 102 can have an angle of 20° or less. The region over the substrate 40 covered with the lower and wider first organic buffer layer 102 includes the region over the substrate 40 covered with the upper and narrower second organic buffer layer 104, and the second constant thickness portion 104b and the second outer portion 104c overlie the first constant thickness portion 102b. Accordingly, the angle at which the gas barrier layer 60 rises is gradually increased. Thus, the gas barrier layer 60 can be prevented from cracking or separating. In the organic EL device 6 of the present embodiment, the gas barrier layer 60 difficult to crack and separate can sufficiently seal the organic EL elements 22.

### Fourth Embodiment

An organic EL device according to a fourth embodiment of the present invention is the same as the organic EL device 2 of the first embodiment except for the structure of the organic buffer layer.

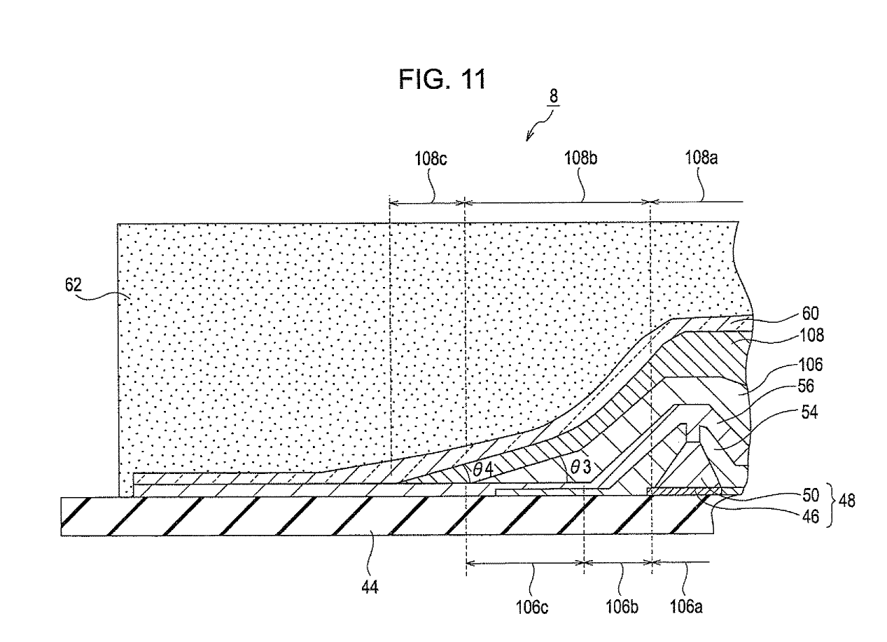

FIG. 11 is a fragmentary enlarged sectional view of an organic EL device 8 according to the fourth embodiment. The organic EL device 8 of the present embodiment has a first organic buffer layer 106 formed on the cathode protection layer 56 so as to overlie all the organic EL elements 22. The entire first organic buffer layer 106 is covered with a second organic buffer layer 108. The entirety of both the first organic buffer layer 106 and the second organic buffer layer 108 are covered with a gas barrier layer 60 widely formed over the cathode protection layer 56.

The first organic buffer layer 106 and the second organic buffer layer 108 are intended to enhance the flatness and adhesion of the gas barrier layer 60 and alleviate the stress in the gas barrier layer 60. The first and second organic buffer layers 106 and 108 are formed by applying and curing the above-described organic buffer layer material in an atmosphere of reduced pressure, and are firmly adhere to each other. The region over the substrate 40 covered with the second organic buffer layer 108 includes the region over the substrate 40 covered with the first organic buffer layer 106.

The first organic buffer layer 106 includes a first coating portion 106a overlying all the organic EL elements 22, a first constant thickness portion 106b surrounding the first coating portion 106a, and a first outer portion 106c surrounding the first constant thickness portion 106b and whose thickness is gradually reduced outward. Since the first organic buffer layer 106 is formed by applying a liquid material, the angle θ3 between the upper surface of the first outer portion 106c and the upper surface of the substrate 40 depends on the thickness of the first constant thickness portion 106b.

The second organic buffer layer 108 includes a second coating portion 108a overlying all the organic EL elements 22, a second constant thickness portion 108b surrounding the second coating portion 108a, and a second outer portion 108c surrounding the second constant thickness portion 108b and whose thickness is gradually reduced outward. The second organic buffer layer 108 is formed by applying a liquid material so that the upper surface of the second coating portion 104a becomes flat.

In the present embodiment, the upper limit of the thickness of the second constant thickness portion 108b is set so that the angle θ4 at which the second outer portion 108c rises from the end of the second organic buffer layer 108 can be 20° or less. The thickness of the first constant thickness portion 106b, or the angle θ3 at which the first organic buffer layer 106 rises, is set so that the second coating portion 108a has a flat surface when the second organic buffer layer 108 is formed with θ4 satisfying the above requirement. In the present embodiment, θ3≈θ4 holds. The thickness of the first organic buffer layer 106 is set in view of the height of the partition structure 48, and also set in view of the percentage of light deviating to the sides of the surface protection member 64 (see FIG. 2) and the sides of the adhesive layer 62 (described below) so that light can efficiently pass through the surface protection member 64, which may have a color filter function, to the upper surface.

The organic EL device 8 of the present embodiment has two organic buffer layers, and the region over the substrate 40 covered with the upper and wider second organic buffer layer 108 includes the region over the substrate 40 covered with the lower and narrower first organic buffer layer 106. Also, the lower and narrower first organic buffer layer 106 is thicker than the upper and wider second organic buffer layer 108. The second constant thickness portion 108b covers the first constant thickness portion 106b and the first outer portion 106c. Thus, the organic EL device 8 according to the third embodiment can produce the same effects as the organic EL device 6 according to the third embodiment.

### Fifth Embodiment

An organic EL device according to a fifth embodiment of the present invention is the same as the organic EL device 4 of the second embodiment except for the structure of the organic buffer layer.

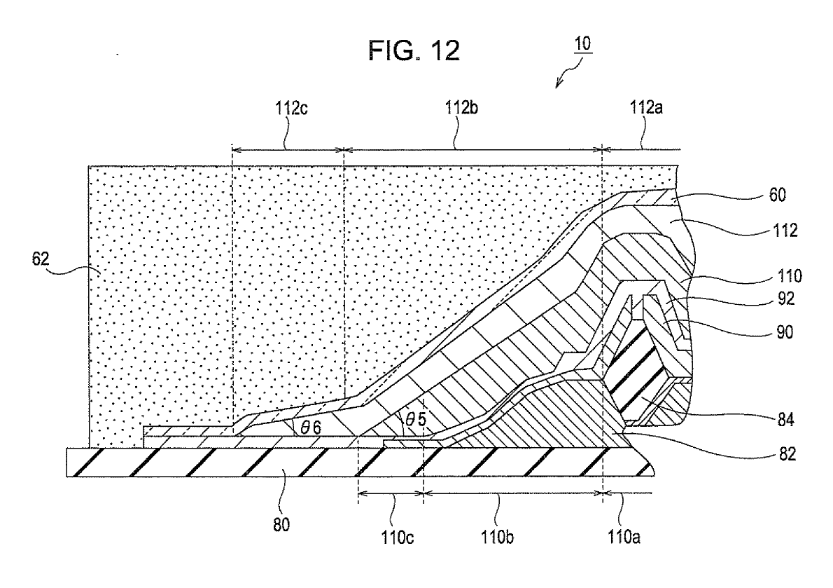

FIG. 12 is a fragmentary enlarged sectional view of an organic EL device 10 according to the fifth embodiment. The organic EL device 10 of the present embodiment has a first organic buffer layer 110 formed on the cathode protection layer 92 so as to overlie all the organic EL elements 74, the pixel partition insulating layer 84 and the planarizing layer 82. The first organic buffer layer 110 is covered with a second organic buffer layer 112 over the cathode protection layer 92. A gas barrier layer 60 is formed over the cathode protection layer 92 and the second organic buffer layer 112 to cover the second organic buffer layer 112.

The cathode protection layer 92, the first organic buffer layer 110 and the first organic buffer layer 112 correspond to the cathode protection layer 56, the first organic buffer layer 106 and the second organic buffer layer 108 in the fourth embodiment. Thus, the first organic buffer layer 110 includes a first coating portion 110a overlying all the organic EL elements 74, a first constant thickness portion 110b surrounding the firs coating portion 110a, and a first outer portion 110c surrounding the first constant thickness portion 110b and whose thickness is gradually reduced outward. The second organic buffer layer 112 includes a second coating portion 112a overlying all the organic EL elements 74, a second constant thickness portion 112b surrounding the second coating portion 112a, and a second outer portion 112c surrounding the second constant thickness portion 112b and whose thickness is gradually reduced outward.

In the present embodiment, the upper limit of the thickness of the second constant thickness portion 112b is set so that the angle θ6 at which the second outer portion 112c rises from the end of the second organic buffer layer 112 can be 20° or less. The thickness of the first constant thickness portion 110b, or the angle θ5 at which the first organic buffer layer 110 rises, is set so that the second coating portion 112a has a flat surface when the second organic buffer layer 112 is formed with θ6 satisfying the above requirement. In the present embodiment, ι5≈θ6 holes. In addition, the thickness of the first organic buffer layer 110 is set in view of the degree of covering the elevations of the partition structure, and the percentage of light deviating to the sides of the adhesive layer 62 (described below) without reaching the lower surface of the color filter substrate 96 (see FIG. 8).

The organic EL device 10 according to the fifth embodiment can produce the same effects as the organic EL device 4 according to the second embodiment.

The organic EL device 10 of the present embodiment has two organic buffer layers, and the region over the substrate 72 covered with the upper and wider second organic buffer layer 112 includes the region over the substrate 72 covered with the lower and narrower first organic buffer layer 110. Also, the lower and narrower first organic buffer layer 110 is thicker than the upper and wider second organic buffer layer 112. The second constant thickness portion 112b covers the first constant thickness portion 110b and the first outer portion 110c. Thus, the organic EL device 10 according to the fifth embodiment can produce the same effects as the organic EL device 8 according to the fourth embodiment.

### Sixth Embodiment

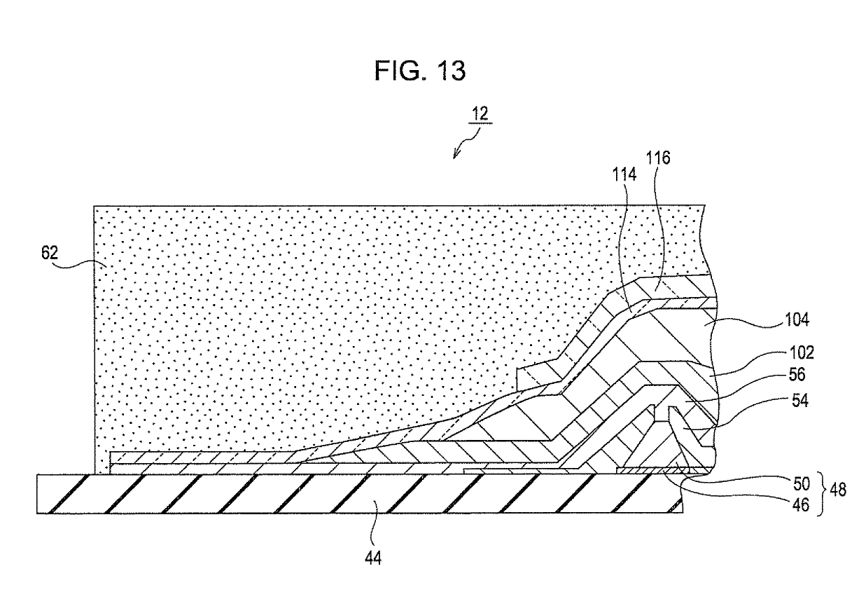

FIG. 13 is a fragmentary enlarged sectional view of an organic EL device 12 according to a sixth embodiment. As is shown in FIG. 13, the organic EL device 12 has the same structure as the organic EL device 6 of the third embodiment except for the gas barrier layer.

The organic EL device 12 of the preset embodiment includes a first gas barrier layer 114 and a second gas barrier layer 116. The first gas barrier layer 114 is disposed over the cathode protection layer 56, the first organic buffer layer 102 and the second organic buffer layer 104, and covers the first organic buffer layer 102 and the second organic buffer layer 104 with firm contact with these organic buffer layers 102 and 104. The second gas barrier layer 116 is disposed on the first gas barrier layer 114 so as to cover the organic EL elements 22, but in such a narrow area as cannot cover the end of the first organic buffer layer 102. The first and the second gas barrier layer 114 and 116 are formed of the same material as the gas barrier layer 60 of the third embodiment, and adhere firmly to each other.

The first gas barrier layer 114 enhances the sealing properties to seal the first organic buffer layer 102, the second organic buffer layer 104 and the organic EL elements 22. The first gas barrier layer 114 has a thickness of 200 to 400 nm. The lower limit of this range is set from the viewpoint of ensuring the sealing properties to seal the sides of the organic buffer layers and their vicinities. The second gas barrier layer 116 enhances the sealing properties to seal the organic EL elements 22. The second gas barrier layer 116 has a thickness of 200 to 800 nm. In the present embodiment, the total thickness of the first gas barrier layer 114 and the second gas barrier layer 116 is limited to less than 1000 nm. This limitation is determined in view of the sealing properties to seal the organic EL elements 22, the possibility of cracking or separating the gas barrier layers, and the manufacturing cost.

The organic EL device 12 according to the sixth embodiment can produce the same effects as the organic EL device 6 according to the third embodiment. In order to enhance the sealing properties, it is required that the gas barrier layer be thick. However, if the entire thickness of the gas barrier layer is increased to the same extent, stress is concentrated on an uneven portion of the gas barrier layer. In the present embodiment, in which the gas barrier layer includes the first gas barrier layer 114 and the second gas barrier layer 116, the portion of the gas barrier layer covering all the organic EL elements 22 has a larger thickness while the portion of the gas barrier layer rising from the end of the first organic buffer layer 102 has a smaller thickness. Consequently, the gas barrier layer enhances the sealing properties to seal the organic EL elements 22 while being prevented from cracking and separating.

### Seventh Embodiment

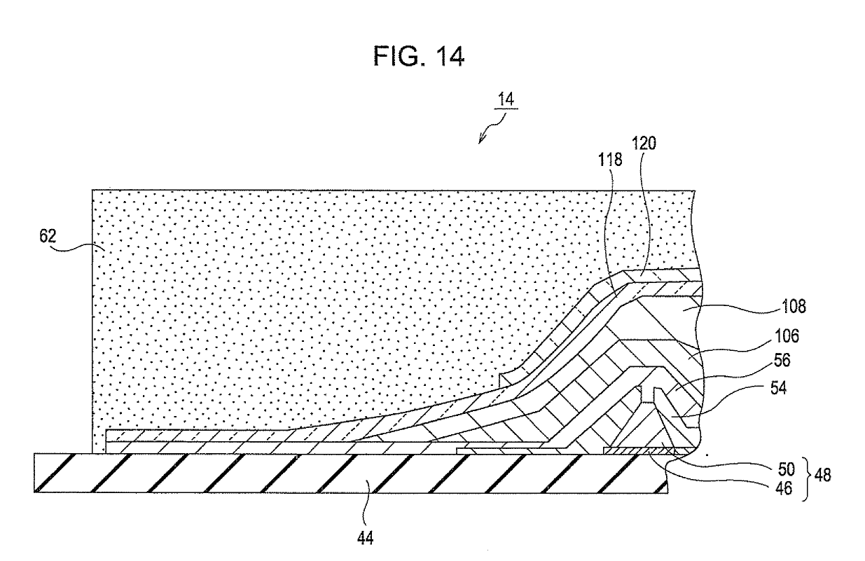

FIG. 14 is a fragmentary enlarged sectional view of an organic EL device 14 according to a seventh embodiment. As is shown in FIG. 14, the organic EL device 14 has the same structure as the organic EL device 8 of the fourth embodiment except for the gas barrier layer. The organic EL device 14 of the present embodiment includes a first gas barrier layer 118 and a second barrier layer 120 corresponding to the first gas barrier layer 114 and the second gas barrier layer 116 in the sixth embodiment.

The organic EL device 14 according to the seventh embodiment can produce the same effects as the organic EL device 8 according to the fourth embodiment. Since the gas barrier layer includes the first gas barrier layer 118 and the second gas barrier layer 120, the gas barrier layer enhances the sealing properties to seal the organic EL elements 22 while being prevented from cracking and separating.

### Eighth Embodiment

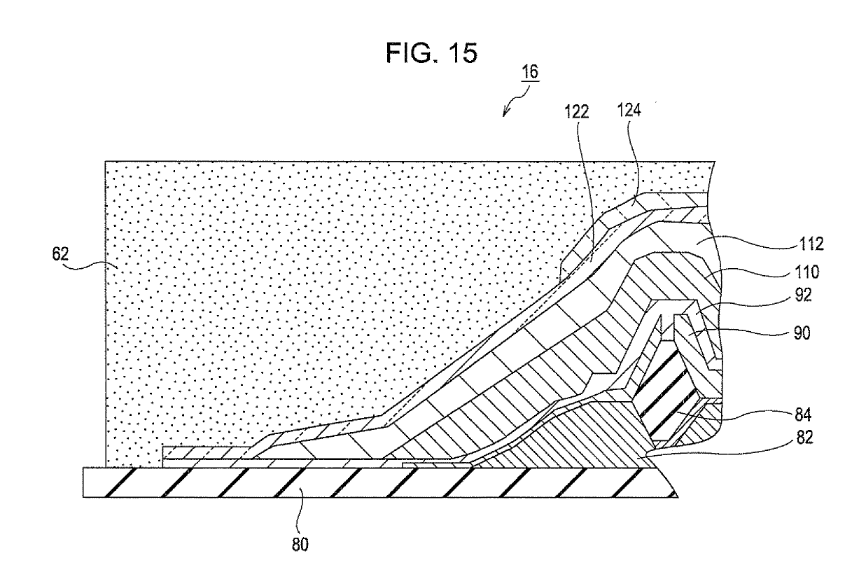

FIG. 15 is a fragmentary enlarged sectional view of an organic EL device 16 according to an eighth embodiment. As is shown in FIG. 15, the organic EL device 16 has the same structure as the organic EL device 10 of the fifth embodiment except for the gas barrier layer. The organic EL device 16 of the present embodiment includes a first gas barrier layer 122 and a second barrier layer 124 corresponding to the first gas barrier layer 118 and the second gas barrier layer 120 in the seventh embodiment.

The organic EL device 16 according to the present embodiment can produce the same effects as the organic EL device 10 according to the fifth embodiment. Since the gas barrier layer includes the first gas barrier layer 122 and the second gas barrier layer 124, the gas barrier layer enhances the sealing properties to seal the organic EL elements 74 while being prevented from cracking and separating.

### Modifications

The organic buffer layer may be constituted of three layers or more. In this instance, two of the organic buffer layers are formed such that the regions over the substrate covered with the two layers are not fully the same and partially have an overlap. This applies to the gas barrier layer. The sixth to eighth embodiments may be modified such that the first gas barrier layer closer to the substrate is covered with the second gas barrier layer farther from the substrate.

Although the second portion of the common cathode layer in the above-described embodiments is continuously extended to follow at least one of the sides of the substrate, part of the region of the side may not have the second portion of the common cathode layer. However, the deoxidation/dehydration ability is higher in the case where the second portion is continuously disposed. The second portion may be continuous over the entire outer region. As the second portion of the common cathode layer has a larger section, the deoxidation/dehydration ability is increased. Accordingly, the dimensions (width and thickness of the section) of the second portion of the common cathode layer are set according to the desired deoxidation/dehydration ability.

The entire disclosure of Japanese Patent Application Nos:2009-088693, filed Apr. 1, 2009 and 2010-077490, filed Mar. 30, 2010 are expressly incorporated by reference herein.

What is claimed is:

1. An organic electroluminescence device comprising on a substrate:
a plurality of first electrodes;
a partition structure having a plurality of openings corresponding to the positions of the first electrodes, the partition structure including an end portion;
an organic luminescent layer;
a second electrode covering the partition structure and the organic luminescent layer, the second electrode including a first portion and a second portion that are separate from each other, the first portion covering the organic luminescent layer and the entire partition structure except the outer portion from the edge of the partition structure, the second portion covering the outer portion from the edge of the partition structure and at least part of the external region around the partition structure; and
a sealing layer or a sealing member covering the second electrode.

2. The organic electroluminescence device according to claim 1, wherein the second electrode contains an alkaline-earth metal.

3. The organic electroluminescence device according to claim 1, wherein the second electrode has a thickness of 1 to 50 nm.

4. The organic electroluminescence device according to claim 1, wherein the second electrode has a thickness of 10 to 30 nm.

5. The organic electroluminescence device according to claim 1, wherein the first portion and the second portion of the second electrode are in the same layer.

6. The organic electroluminescence device according to claim 1, wherein the second portion of the second electrode is disposed over the entirety of an outer region of the surface of the substrate.

7. The organic electroluminescence device according to claim 1, wherein the second portion of the second electrode is electrically floated.
